(19) United States
(12) Patent Application Publication
(10) Pub. No.: US 2026/0122996 A1
(43) Pub. Date: Apr. 30, 2026

(54) SEMICONDUCTOR STRUCTURE FOR HIGH ELECTRON MOBILITY TRANSISTOR

(71) Applicant: HiPer Semiconductor Inc., George Town (KY)

(72) Inventor: Po-Jung LIN, Zhubei City (TW)

(21) Appl. No.: 19/307,475

(22) Filed: Aug. 22, 2025

(30) Foreign Application Priority Data
Oct. 24, 2024 (TW) 113140599

(51) Int. Cl. H10D 62/815; H10D 30/47; H10D 62/10; H10D 62/60

(52) U.S. Cl. CPC H10D 62/8164; H10D 30/475; H10D 62/102; H10D 62/60; H10D 62/8171

(57) ABSTRACT

A semiconductor structure includes a substrate, a nucleation layer, a superlattice layer, a first graded layer, a second graded layer, a breakdown voltage layer, a channel layer, and a barrier layer. The nucleation layer is disposed between the substrate and the superlattice layer. The superlattice layer is formed by alternating a high-aluminum layer and a low-aluminum layer, with an average aluminum composition ranging from 70% to 90%. The first graded layer has an average aluminum composition ranging from 40% to 70%. The second graded layer is disposed on the first graded layer and has an average aluminum composition ranging from 30% to 40%. The channel layer is disposed between the breakdown voltage layer and the barrier layer. The total thickness from the nucleation layer to the barrier layer ranges from 700 nm to 3000 nm.

### BACKGROUND

### 1. Technical Field

The present invention relates to a semiconductor structure, and more particularly to a semiconductor structure for a high electron mobility transistor (HEMT).

### 2. Description of the Related Art

For a high electron mobility transistor (HEMT), vertical breakdown voltage and structural stability are both critically important. However, due to the tightly stacked structure of the semiconductor structure used in HEMTs, various conventional technologies have been proposed to improve vertical breakdown voltage, such as those disclosed in Taiwan Patent No. 1678723B and U.S. Pat. Nos. 9,233,844, 11,942,521B2, 8,592,823B2, and 9,245,991. Nevertheless, these references do not address how to improve the vertical breakdown voltage of HEMT semiconductor structures operating in the medium voltage range (100V to 250V), nor do they disclose methods for reducing the dynamic resistance of such structures. Therefore, how to improve the vertical breakdown voltage, dynamic resistance, and structural stability of HEMT semiconductor structures rated below 250V remains a topic worthy of further study.

### SUMMARY

An objective of the present invention is to provide a semiconductor structure including a superlattice layer formed by alternately stacking a high-aluminum layer and a low-aluminum layer, with the alternating arrangement repeated a plurality of times, so as to enable a high electron mobility transistor to achieve higher vertical breakdown voltage and lower dynamic resistance.

To achieve the above objective, the semiconductor structure for a high electron mobility transistor of the present invention includes a substrate, a nucleation layer, a superlattice layer, a first graded layer, a second graded layer, a breakdown voltage layer, a channel layer, and a barrier layer. The nucleation layer is disposed on the substrate, and the superlattice layer is disposed on the nucleation layer. The superlattice layer is formed by alternately stacking a high-aluminum layer and a low-aluminum layer, with the alternating arrangement repeated a plurality of times. The superlattice layer has an average aluminum composition between 70% and 90%. The first graded layer is disposed on the superlattice layer and has an average aluminum composition between 40% and 70%. The second graded layer is disposed on the first graded layer and has an average aluminum composition between 30% and 40%. The breakdown voltage layer is disposed on the second graded layer, the channel layer is disposed on the breakdown voltage layer, and the barrier layer is disposed on the channel layer. The total thickness from the nucleation layer to the barrier layer is between 700 nm and 3000 nm.

According to one embodiment of the present invention, the semiconductor structure for a high electron mobility transistor of the present invention has a breakdown voltage of less than 250 V.

The present invention employs a superlattice layer composed of a single alternating structure repeated multiple times to reduce the dynamic resistance of the semiconductor structure. Additionally, the present invention specifies that, among the two graded layers, the one positioned closer to the breakdown voltage layer has an average aluminum composition between 30% and 40%, thereby enhancing the vertical breakdown voltage of the semiconductor structure. As a result, the high electron mobility transistor utilizing the semiconductor structure of the present invention achieves higher vertical breakdown voltage, lower dynamic resistance, and improved structural stability.

### BRIEF DESCRIPTION OF THE DRAWINGS

FIG. 1 is a schematic diagram illustrating an embodiment of a semiconductor structure for a high electron mobility transistor (HEMT) according to the present invention.

FIG. 2 is a comparison chart showing the breakdown voltages of semiconductor structures in which the average aluminum composition of the second graded layer is greater than 30% versus less than 30%.

FIG. 3A is a schematic diagram illustrating a reference sample used for dynamic resistance testing and a semiconductor structure for a HEMT according to the present invention used for the same purpose.

FIG. 3B is a comparison graph showing the measured dynamic resistance of the semiconductor structure of the present invention versus that of a reference sample lacking the superlattice structure.

### DETAILED DESCRIPTION OF THE EMBODIMENTS

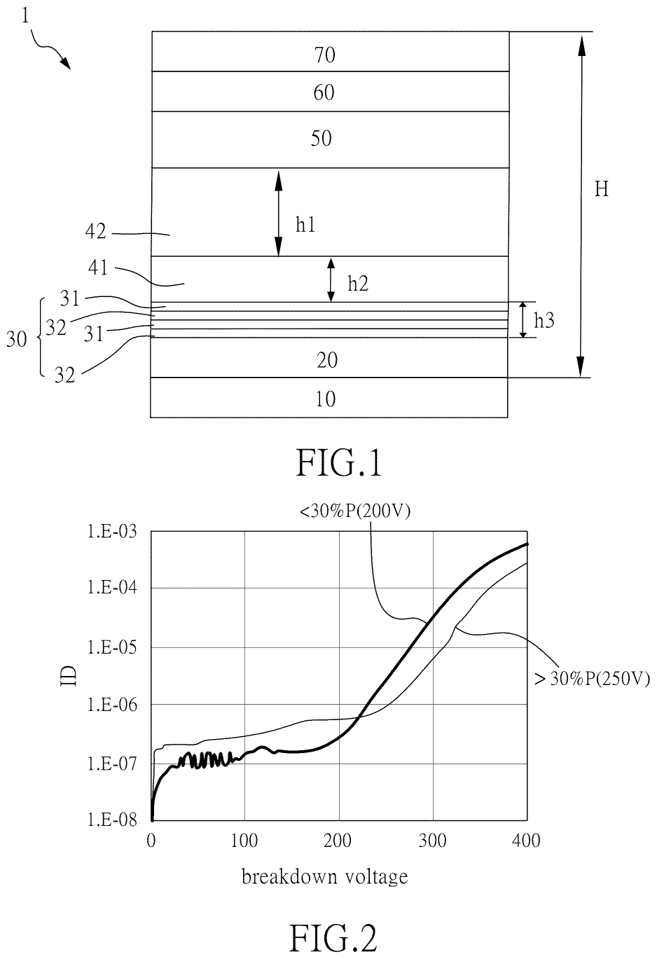

For a better understanding of the present invention, please refer to FIG. 1 and FIG. 2, which respectively illustrate an embodiment of a semiconductor structure for a high electron mobility transistor (HEMT) according to the present invention, and a comparison chart showing the breakdown voltages of semiconductor structures in which the average aluminum composition of the second graded layer is greater than 30% versus less than 30%.

As shown in FIG. 1, in this embodiment, the semiconductor structure 1 for a high electron mobility transistor (HEMT) of the present invention includes a substrate 10, a nucleation layer 20, a superlattice layer 30, a first graded layer 41, a second graded layer 42, a breakdown voltage layer 50, a channel layer 60, and a barrier layer 70.

The nucleation layer 20 is disposed on the substrate 10, and the superlattice layer 30 is disposed on the nucleation layer 20. The superlattice layer 30 is formed by alternately stacking a high-aluminum layers 31 and a low-aluminum layers 32, with the alternating arrangement repeated a plurality of times. The superlattice layer 30 has an average aluminum composition ranging from 70% to 90%. The first graded layer 41 is disposed on the superlattice layer 30 and has an average aluminum composition ranging from 40% to 70%. The second graded layer 42 is disposed on the first graded layer 41 and has an average aluminum composition ranging from 30% to 40%. The breakdown voltage layer 50 is disposed on the second graded layer 42, the channel layer 60 is disposed on the breakdown voltage layer 50, and the barrier layer 70 is disposed on the channel layer 60. The total thickness from the nucleation layer 20 to the barrier layer 70 is referred to as thickness H, which ranges from 700 nm to 3000 nm.

Furthermore, as shown in FIG. 2, when the average aluminum composition of the second graded layer 42 in this embodiment exceeds 30%—for example, 34% or 35%—the breakdown voltage (i.e., vertical breakdown voltage) of the HEMT utilizing the semiconductor structure 1 of the present invention can reach 250 V. This value is significantly higher than the 200 V achieved when the average aluminum composition of the second graded layer 42 is below 30%. Therefore, configuring the average aluminum composition of the second graded layer 42 within the range of 30% to 40% can effectively improve the breakdown voltage (vertical breakdown voltage) of the semiconductor structure of the present invention.

As shown in FIG. 1, in this embodiment, the semiconductor structure 1 of the present invention is applicable to high electron mobility transistors (HEMTs) having a breakdown voltage of 250 V or below (i.e., medium-voltage HEMTs). The substrate 10 is a p-type silicon substrate, and the nucleation layer 20 is an aluminum nitride (AlN) layer. The superlattice layer 30 is formed by alternating high-aluminum layers 31 and low-aluminum layers 32, wherein the low-aluminum layer 32 is in contact with the nucleation layer 20, and the high-aluminum layer 31 is stacked on the low-aluminum layer 32. In this embodiment, the high-aluminum layer 31 is an AlN layer, and the low-aluminum layer 32 is an aluminum gallium nitride (AlGaN) layer. However, the present invention is not limited to this configuration, as long as the superlattice layer 30 includes alternating high-aluminum layers and low-aluminum layers, and the average aluminum composition of the superlattice layer 30 falls within the range of 70% to 90%.

According to one embodiment of the present invention, the nucleation layer 20 has a thickness of 150 nm, the high-aluminum layer 31 has a thickness of 5 nm, and the low-aluminum layer 32 has a thickness of 20 nm. The superlattice layer 30 is doped with iron (Fe), with a doping concentration ranging from 5E16 to 5E18 cm⁻³. The high-aluminum layer 31 and the low-aluminum layer 32 are alternately stacked in six repetitions, resulting in a total thickness of the superlattice layer 30 of 150 nm.

As shown in FIG. 1, in this embodiment, the first graded layer 41 is an AlₓGa₁₋ₓN layer, and the second graded layer 42 is an Al_{γ}Ga_{1-γ}N layer, where x is, for example, 0.55 to achieve an average aluminum composition of 40% to 70% in the first graded layer 41, and y is, for example, 0.34 to achieve an average aluminum composition of 30% to 40% in the second graded layer 42. Additionally, in this embodiment, the thickness H2 of the first graded layer 41 is less than the thickness H1 of the second graded layer 42, and the thickness H1 of the second graded layer 42 is greater than the thickness H3 of the superlattice layer 30. According to one embodiment of the present invention, the relationship among the three thicknesses satisfies H1>H2>H3. It is noted that although the average aluminum composition of the first graded layer 41 is between 40% and 70%, and that of the second graded layer 42 is between 30% and 40%—thus generally x>y—this is not intended to limit the present invention, and x and y can be independently selected.

According to one embodiment of the present invention, the first graded layer 41 and the second graded layer 42 are doped with iron. The iron doping concentration in the first graded layer 41 is between 5E16 to 5E18 cm⁻³. The second graded layer 42 is co-doped with iron and carbon, wherein the iron doping concentration is between 5E16 to 5E18 cm⁻³, and the carbon doping concentration is between 1E17 to 1E20 cm⁻³. In this embodiment, the breakdown voltage layer 50 is a gallium nitride (GaN) layer, and its thickness is greater than that of the second graded layer 42. The thickness of the breakdown voltage layer 50 is 500 nm, and it is doped with carbon at a carbon doping concentration ranging from 1E17 to 1E20 cm⁻³. The channel layer 60 is also a GaN layer with a thickness of 300 nm, which contributes to enhancing the vertical breakdown capability of the semiconductor structure 1 of the present invention. The barrier layer 70 is an aluminum gallium nitride (AlGaN) layer.

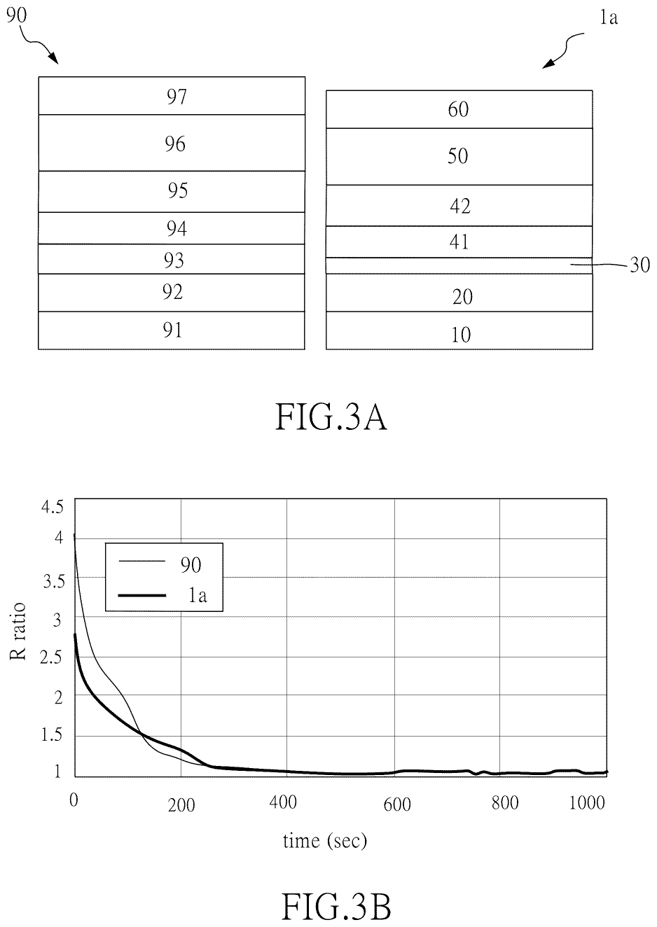

Please refer to FIGS. 3A and 3B, and Table 1. FIG. 3A is a schematic diagram illustrating a reference sample used for dynamic resistance testing, as well as the semiconductor structure for a high electron mobility transistor (HEMT) according to the present invention, also used for dynamic resistance testing. FIG. 3B is a comparison graph showing the measured dynamic resistance of the semiconductor structure of the present invention in contrast to that of a reference sample lacking the superlattice structure.

As shown in FIG. 3A, the reference sample 90 used for testing includes a substrate 91, a nucleation layer 92, a graded layer 93, a first graded layer 94, a second graded layer 95, a breakdown voltage layer 96, and a channel layer 97. The substrate 91 is a p-type silicon substrate. The nucleation layer 92 is an aluminum nitride (AlN) layer with a thickness of 150 nm. The graded layer 93 is an aluminum gallium nitride (AlGaN) layer with a thickness of 300 nm and is doped with iron, having an aluminum composition of 70.2%. The first graded layer 94 is an AlGaN layer with a thickness of 300 nm and an aluminum composition of 55.6%. The second graded layer 95 is an AlGaN layer with a thickness of 400 nm and an aluminum composition of 34.2%. The breakdown voltage layer 96 is a gallium nitride (GaN) layer with a thickness of 500 nm and is doped with carbon. The channel layer 97 is a GaN layer with a thickness of 300 nm.

As shown in FIG. 3A, in the semiconductor structure 1a of the present invention used for testing, the structures and compositions of the substrate 10, nucleation layer 20, breakdown voltage layer 50, and channel layer 60 are identical to those of the substrate 91, nucleation layer 92, breakdown voltage layer 96, and channel layer 97 of the reference sample 90. The superlattice layer 30 of the semiconductor structure 1a has a thickness of 150 nm, an aluminum composition of 71.1%, and is doped with iron. The first graded layer 41 is an AlGaN layer with a thickness of 300 nm and an aluminum composition of 55.3%. The second graded layer 42 is an AlGaN layer with a thickness of 400 nm and an aluminum composition of 34.2%.

As shown in FIG. 3B and Table 1, compared to the reference sample 90 that does not include the superlattice layer 30, the semiconductor structure 1a of the high electron mobility transistor (HEMT) according to the present invention exhibits significantly lower dynamic resistance. This confirms that the superlattice layer 30 of the present invention effectively reduces the dynamic resistance of the semiconductor structure 1a, thereby enabling the HEMT incorporating the semiconductor structure 1a to achieve improved device characteristics. The enhanced structure also improves the device's stability and electrical reliability. In addition, the superlattice layer 30 strengthens the mechanical integrity of the semiconductor structure 1a.

TABLE 1
Comparison of Dynamic Resistance Between the
Reference Sample and the Present Invention

| Sub. Stress | | reference sample (90) | | present invention (1a) | |
|---|---|---|---|---|---|
| +200 V | before | 29 | 29 | 28 | 26 |
| | Stress | | | | |
| | after Stress | 143(4.9) | 117(4.0) | 83(2.9) | 72(2.8) |

The present invention utilizes a superlattice layer 30 composed of a single alternating structure, repeated multiple times, with an average aluminum composition ranging from 70% to 90%, to reduce the dynamic resistance of the semiconductor structures 1 and 1a. Furthermore, by setting the average aluminum composition of the second graded layer 42—positioned adjacent to the breakdown voltage layer—between 30% and 40%, the vertical breakdown voltage of the semiconductor structure 1 is enhanced. Accordingly, high electron mobility transistors incorporating the semiconductor structures 1 or 1a of the present invention exhibit higher vertical breakdown voltage, lower dynamic resistance, and improved structural stability, thereby overcoming the limitations of the prior art.)

It should be noted that many of the above-mentioned embodiments are given as examples for description, and the scope of the present disclosure should be limited to the scope of the following claims and not limited by the above embodiments.

What is claimed is:

1. A semiconductor structure for a high electron mobility transistor (HEMT), comprising:
a substrate;
a nucleation layer disposed on the substrate;
a superlattice layer disposed on the nucleation layer, wherein the superlattice layer is formed by alternately stacking a high-aluminum layer and a low-aluminum layer, with the alternating arrangement repeated a plurality of times, and wherein an average aluminum composition of the superlattice layer is between 70% and 90%;
a first graded layer disposed on the superlattice layer, wherein an average aluminum composition of the first graded layer is between 40% and 70%;
a second graded layer disposed on the first graded layer, wherein an average aluminum composition of the second graded layer is between 30% and 40%;
a breakdown voltage layer disposed on the second graded layer;
a channel layer disposed on the breakdown voltage layer; and
a barrier layer disposed on the channel layer, wherein a thickness from the nucleation layer to the barrier layer is between 700 nm and 3000 nm.

2. The semiconductor structure as claimed in claim 1, wherein the high electron mobility transistor is a high electron mobility transistor with a breakdown voltage of less than 250 V.

3. The semiconductor structure as claimed in claim 1, wherein the thickness of the first graded layer is less than the thickness of the second graded layer.

4. The semiconductor structure as claimed in claim 3, wherein the first graded layer is an AlₓGa₁₋ₓN layer, the second graded layer is an Al_{γ}Ga_{1-γ}N layer, and both the first graded layer and the second graded layer are doped with iron.

5. The semiconductor structure as claimed in claim 1, wherein the thickness of the second graded layer is greater than the thickness of the superlattice layer.

6. The semiconductor structure as claimed in claim 1, wherein the high-aluminum layer is an AlN layer, and the low-aluminum layer is an AlGaN layer.

7. The semiconductor structure as claimed in claim 1, wherein the breakdown voltage layer is doped with carbon.

8. The semiconductor structure as claimed in claim 1, wherein the superlattice layer is doped with iron.

9. The semiconductor structure as claimed in claim 1, wherein the second graded layer is doped with carbon and iron.

10. The semiconductor structure as claimed in claim 1, wherein the first graded layer is doped with iron.

11. The semiconductor structure as claimed in claim 1, wherein the substrate is a p-type silicon substrate.

12. The semiconductor structure as claimed in claim 1, wherein the low-aluminum layer is in contact with the nucleation layer.

13. The semiconductor structure as claimed in claim 1, wherein the thickness of the breakdown voltage layer is greater than the thickness of the second graded layer.

14. The semiconductor structure as claimed in claim 1, wherein the thickness of the channel layer is less than the thickness of the breakdown voltage layer.

15. The semiconductor structure as claimed in claim 1, wherein a carbon doping concentration in the breakdown voltage layer and the second graded layer is between 1E17 cm⁻³ and 1E20 cm⁻³.

16. The semiconductor structure as claimed in claim 1, wherein each of the first graded layer, the second graded layer, and the superlattice layer has an iron doping concentration in a range between 5E16 cm⁻³ and 5E18 cm⁻³.
